(19) United States
(12) Patent Application Publication
(10) Pub. No.: US 2025/0231654 A1
(43) Pub. Date: Jul. 17, 2025

(54) IN-MOLD TOUCH FILM INTEGRATED FLEXIBLE PRINTED CIRCUIT WITH TOUCH COMPONENTS

(71) Applicant: WHIRLPOOL CORPORATION, Benton Harbor, MI (US)

(72) Inventor: Sithaarth T. SUBRAMANIYAM, St. Joseph, MI (US)

(21) Appl. No.: 18/414,557

(22) Filed: Jan. 17, 2024

(51) Int. Cl. G06F 3/045; D06F 34/32; G06F 3/041; H05K 1/18

(52) U.S. Cl. CPC G06F 3/045; G06F 3/0412; H05K 1/189; D06F 34/32

(57) ABSTRACT

A consumer appliance or touch panel interface, as provided herein, may include a fascia panel, a Flexible Printed Circuit (FPC) with touch-responsive components, and resistive material arranged within. The FPC may be bonded directly to a touch film on the fascia panel. The resistive material may encapsulate the fascia or be positioned between the fascia and FPC. The resistive material provides thermal insulation and may be made of silicon. The silicon resistive material positioned between the fascia and the FPC may help to reduce shearing in the bonding region. The fascia may accommodate non-linear curvatures. The FPC has distinct regions for touch interactivity and illumination feedback, without a need for additional touch circuitry.

### TECHNICAL FIELD

Aspects of the disclosure relate generally to printed circuit boards with in-molded electronic film mounted directly to the printed circuit boards, such as may be used in control panels for appliances.

### BACKGROUND

Appliances typically feature a user interface, central to their functionality, often made up of buttons, touch panels, or other command-input components. The user interface is helpful in receiving user commands, regulating appliance operations, and providing feedback. The integration of touch films directly onto these interfaces has gained traction aiming to create more compact designs. A notable method is the utilization of in-molded films, embedded with electronic components. This is accomplished by printing circuitry onto these films using conductive materials, effectively minimizing the need for multiple circuit boards, and thereby shrinking the interface's footprint.

The connection between the in-molded electronics and their corresponding circuit boards frequently necessitates intermediate connection elements. Often, connectors like ribbon cables are employed for this purpose. These additional connectors, while facilitating the connection, inadvertently increase the complexity and size of the user interface. Moreover, they introduce vulnerabilities—these connectors, over time and especially in high-vibration environments, may loosen or disconnect, leading to reduced performance or system unavailability.

### SUMMARY

A display structure for appliances is presented. This structure includes a fascia panel and a flexible printed circuit (FPC), which incorporates a touch film with touch-responsive components. The FPC and the fascia panel are integrated to create a unified display structure assembly. Additionally, a resistive substance is placed between the fascia panel and the FPC to provide thermal insulation.

The fascia of the display structure may be made of a polymeric material. The FPC may be seamlessly adhered to the fascia panel, forming a single, unified assembly. This assembly allows the fascia panel to be flexible around non-linear curvatures. The fascia panel may be designed with a forward-facing surface and an opposite rear-facing surface, with the FPC bonded to this rear-facing surface.

The resistive substance used for thermal insulation is selected from suitable materials such as potting or plastic. The display structure may include a graphics film adjacent to the FPC. Both the FPC and the graphics film form a unified assembly with distinct regions dedicated to touch interactivity and illumination feedback. The FPC in this assembly may further include an integrated touch driver and a Light Emitting Diode (LED) driver. A tail structure may extend perpendicularly from the touch film, and during assembly, a device arm secures this tail structure. Silicone may be used between the fascia panel and the FPC to prevent shear.

In another embodiment, a display structure includes a plastic housing, a graphics film adjacent to this housing, and an FPC situated between the graphics film and the plastic housing. The FPC may have designated touch areas and light areas for touch interactivity and illumination feedback. In this embodiment, the FPC is also joined to a fascia panel in a seamless assembly. A touch film may be integrated with the FPC in this structure. The FPC may further include a touch driver and an LED driver. The touch areas of the FPC may be made of silver traces, Indium Tin Oxide, or polymer dot technology. The plastic housing of the display structure may be made using techniques like In-Mold Labeling, In-Mold Decorating, and pad printing.

Another embodiment of a display device for an appliance is presented. The display device comprises an FPC with touch-sensitive components directly bonded to a touch film, a fascia combined with the touch film and the FPC encapsulated by plastic, silicone placed between the fascia and FPC to prevent shear, and a tail extending from the touch film to be held by a device during assembly.

### BRIEF DESCRIPTION OF THE DRAWINGS

The embodiments of the present disclosure are pointed out with particularity in the appended claims. However, other features of the various embodiments will become more apparent and will be best understood by referring to the following detailed description in conjunction with the accompany drawings in which:

FIG. 1 illustrates a perspective view of an appliance according to an embodiment of the present disclosure.

FIG. 2 illustrates a rear perspective view of an internal portion of an interface of an appliance.

FIG. 3. illustrates a profile view of a user interface according to an embodiment of the disclosure.

FIG. 4. provides an exploded view of a user interface according to an embodiment of the present disclosure.

FIG. 5 provides an exploded view of a user interface according to another embodiment of the present disclosure.

FIG. 6 illustrates a profile view of a user interface according to an embodiment of the present disclosure.

### DETAILED DESCRIPTION

As required, detailed embodiments of the present invention are disclosed herein; however, it is to be understood that the disclosed embodiments are merely exemplary of the invention that may be embodied in various and alternative forms. The figures are not necessarily to scale; some features may be exaggerated or minimized to show details of particular components. Therefore, specific structural and functional details disclosed herein are not to be interpreted as limiting, but merely as a representative basis for teaching one skilled in the art to variously employ the present invention.

The disclosure relates to in-molding a touch film without an intermediate Printed Circuit Board (PCB). In one example, touch-related components are on a Flexible Printed Circuit (FPC) bonded directly to the touch film. The bonded assembly is then in-molded along with the aesthetic portion of the assembly.

For the FPC to remain intact and functional during the molding process, protective measures may be incorporated into the assembly. Additionally, a touch film may be adhered to the fascia panel in a single, seamless manner. The fascia may also be made from a polymeric composition, which may be configured for flexibility. A resistive substance, selected from potting or plastic, may provide thermal insulation between the fascia and FPC. The resistive substance may also encapsulate the FPC. The resistive substance may be one of silicone disposed between the components, which may be used to reduce potential shearing in the bonding area that may occur due to the dynamics of material flow during molding. In certain examples, the FPC may include a tail structure extending mostly perpendicular from a touch film. Either a cam or a robot arm may be used to position the tail of the FPC to remain securely attached throughout the molding procedure. In other embodiments either potting or a specified plastic component may be incorporated to provide a protective barrier against temperatures typically encountered during the molding process.

By integrating touch components with the touch film, touch screen response times and a strong signal to noise ratio may be achieved. Without the need for a separate PCB in the assembly the manufacturing process may be simplified. The fascia, when combined with the touch film, may be assembled directly with the Electronic Control Module (ECM). Similarly, the light box, when equipped with the Light Emitting Diode (LED) PCB, may be assembled directly with the ECM. For the molding of the fascia a variety of molding technologies are contemplated such as In-Mold Labeling (IML), In-Mold Decorating (IMD), or even molded plastic complemented with pad print. The touch film itself may be adaptable with technologies ranging from low-resolution to high-resolution, polymer dot, silver traces, Indium Tin Oxide (ITO), and other suitable technologies.

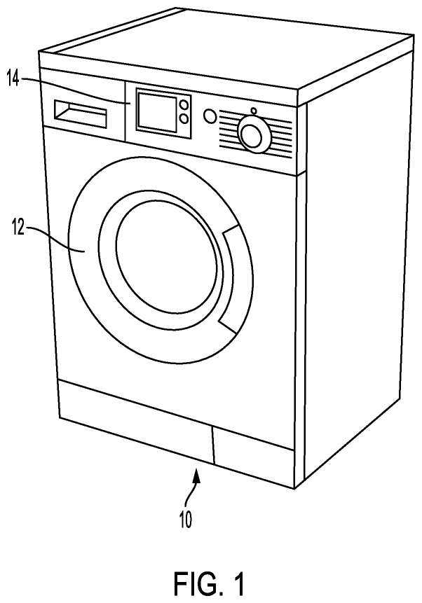

Referring now to the drawings, FIG. 1 illustrates a laundry treating appliance 10 according to an aspect of the disclosure may be any laundry treating appliance 10 that performs a cycle of operation to clean or otherwise treat laundry items placed therein. The laundry treating appliance 10 is illustrated herein as a horizontal axis, front-load laundry treating appliance 10, such as, but not limited to, a washing machine or a laundry dryer. However, it will be understood that the embodiments of the present disclosure may have applicability in other horizontal axis laundry treating appliances, non-limiting examples of which include a combination washing machine or dryer, a refreshing/revitalizing machine, an extractor, or a non-aqueous washing apparatus, or also a horizontal axis laundry treating appliance that is top-loading. Depending on the configuration, it is possible for the embodiments to have applicability in vertical axis laundry treating appliances and other appliances having a door, whether it be hinged, slidable, or otherwise attached to a cabinet, with access to a treating chamber. The laundry treating appliance shares many features of a conventional automated clothes washer and/or dryer, which will not be described in detail herein except as necessary for a complete understanding of the exemplary embodiments in accordance with the present disclosure.

The laundry treating appliance 10 may include a structural support assembly comprising a cabinet 12 defining a housing within which a laundry holding assembly resides. The cabinet may be a housing having a chassis and/or a frame, defining an interior, enclosing components typically found in a conventional washing machine or drying machine. The laundry treating appliance 10 may include a user interface 14. The user interface 14 may include functionality such as to allow a user to select different washing or drying cycles, adjust settings, and monitor the progress of the laundry treatment. The user interface 14 may feature touch surfaces, buttons, dials, and a digital display for enhanced usability and feedback. Additionally, user interface 14 may be on a primary or secondary surface of the laundry treating appliance 10. Conventional washing machine or drying machine components are not described in detail but are described briefly as needed to provide an illustrative environment to support a complete understanding of aspects of the present disclosure.

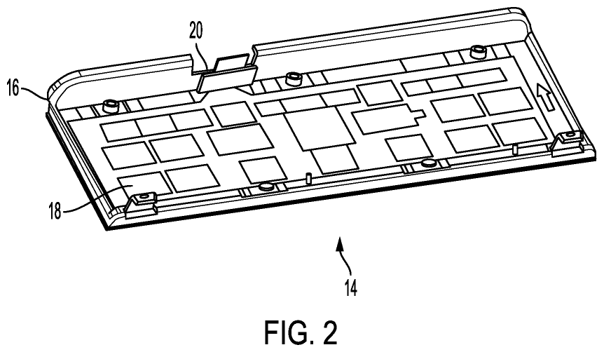

FIG. 2 illustrates the user interface 14 with a fascia 16 and a touch film with flexible printed circuit (FPC) 18 in-molded together. The user interface 14 may also include a protective sheet 20 between the fascia 16 and the touch film with FPC 18 in-molded together. The fascia 16 may be made of a polymeric material that is designed to be flexible, even around non-linear curvatures. The fascia 16 defines a forward-facing surface and a rear-facing surface opposite the forward-facing surface. The touch film with FPC 18 may be bonded to the rear-facing surface of the fascia 16. This touch film FPC 18 may integrate a touch film having touch-responsive components. The integration may be done without an intermediate touch circuit board. Distinct regions on the touch film with FPC 18 may be configured for touch interactivity and illumination feedback. Furthermore, the touch film with FPC 18 may incorporate an integrated touch driver and a light emitting diode (LED) driver.

For durability and functionality, the silicon sheet 20 may be arranged between the fascia 16 and the touch film with FPC 18. The protective sheet 20 may function as a resistive substance that offers thermal insulation, minimizing the transfer of heat between the components and to a user. Additionally, the protective sheet 20 may provide mechanical stability, reducing shear between the fascia panel 16 and the touch film with FPC 18. While described herein as a protective sheet 20, it may be made of silicone or other materials or combinations of materials that may be suitable for the purpose such as other polymer-based elastomers. The protective sheet 20 may aid to prevent shearing created by the material flow during bonding.

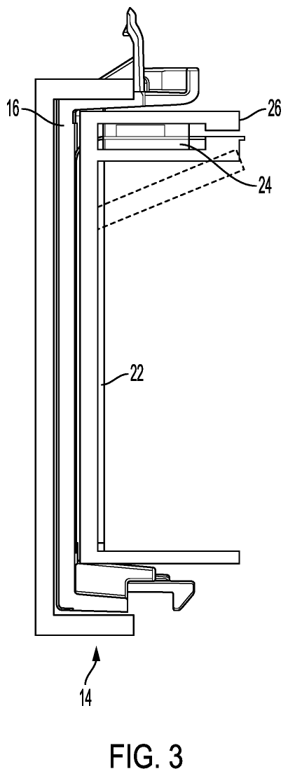

Referring now to FIG. 3, which presents a side cross-sectional view of the user interface 14 designed for the appliance. The components of the user interface 14 comprise the fascia 16 and the touch film combined with a flexible printed circuit (FPC) 18. The fascia 16, may be made from a polymeric material. The fascia 16 may additionally be designed to exhibit a capability to flex, conforming to non-linear curvatures if required. The fascia 16 has a forward-facing surface for user interaction and a rear-facing surface. Integrated onto this rear-facing surface is the touch film with FPC 18, attached to form a uniform assembly between the fascia 16 and the touch film with FPC 18. The uniform seamless assembly between the fascia 16 and touch film with FPC 18 may be joined or bonded together in a manner suitable that secures the two. The touch film with FPC 18 may provide touch interactivity through its touch-responsive components and may also be designed to house distinct regions for illumination feedback.

To help increase the durability of the user interface 14, a resistive substance 20 may be arranged between the fascia 16 and the touch film with FPC 18. This resistive substance 20 may serve as a protective substance serving as a thermal insulator, minimizing heat transfer between the layers and to a user, as well as aiding in the prevention of mechanical shear stresses between the fascia 16 and the touch film with FPC 18 during use. Potential materials for this resistive substance 20 encompass potting, plastic, or other apt materials, insulating the inner workings from external factors. The potting or plastic may be used to encapsulate the fascia 16 or be positioned between the fascia 16 and FPC 18. The touch film portion of the touch film with FPC 18, may extend to include a tail structure 22, perpendicular to the main interface. This tail structure 22 may be used during the assembly process, allowing for secure connection and alignment using a dedicated device arm.

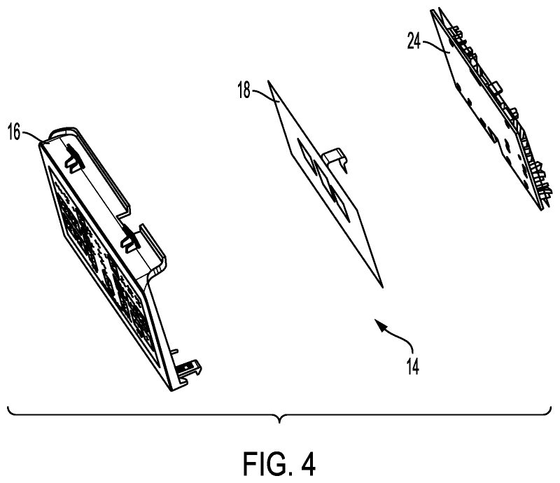

Turning now to FIG. 4, FIG. 4 shows the user interface 14 according to one embodiment of the disclosure. The user interface 14 comprises the fascia 16, touch film with flexible printed circuit (FPC) 18, and a touch Printed Circuit Board Assembly (PCBA) 24. The outer layer of the fascia 16, may be made from a polymeric material. This design may allow the fascia 16 to conform to various shapes, including non-linear curvatures. The fascia 16 has both a forward-facing surface, designed to accommodate components for user interaction, and a rear-facing surface for component attachment. The decorative portions of the fascia 16 may be done by In-Mold Labeling (IML), In-Mold Decorating (IMD), or even molded plastic complemented with pad print.

The touch film with FPC 18 may be bonded to the rear-facing surface of the fascia 16. The touch film with FPC 18 may have touch-responsive components that enable touch interactivity on the fascia's surface. Additionally, specific regions on the touch film with FPC 18 may provide illumination feedback. The touch film with FPC 18, when assembled with fascia 16, provides a rear perspective view of the internal components of user interface 14, as illustrated in FIG. 2. The touch film with FPC 18 may be made designed as low-resolution or high-resolution. The conductive traces for the touch portion of the touch film with FPC 18 may be made from silver traces, Indium Tin Oxide, or polymer dot technology.

Adjacent to the touch film with FPC 18 is the touch PCBA 24. The touch PCBA 24 interprets signals from the touch film with FPC 18. While the touch film with FPC 18 explicitly incorporates touch components, it may also accommodate other input mechanisms such as knobs, dials, or switches. The touch PCBA 24 is capable of interpreting signals from these additional mechanisms. Between the fascia 16 and the touch film with FPC 18, the resistive substance 20 as shown in FIG. 2 may be placed. This substance may offer thermal insulation, preventing heat from the touch PCBA 24 from reaching the forward-facing surface of the fascia 16. Protective substances, such as potting or plastic, may also be used to encase the components, providing added protection.

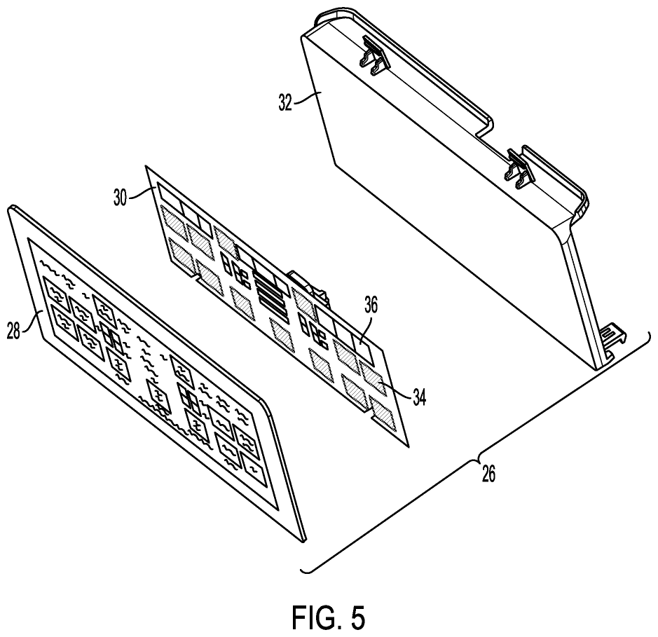

Referring now to FIG. 5, FIG. 5 shows an exploded view of a user interface 26 according to another embodiment. The user interface 26 comprises an In-Mold Labeling (IML) decoration film with graphics 28 also referred to as a graphics film 28, an FPC assembly 30 with touch driver 34, light emitting diode (LED) driver 36, and a connector for power input 38, with a structural plastic 32 may be in-molded together. The uppermost layer, the IML decoration film 28 may provide visuals and instructions for a user. Other graphic printing alternatives may be used such as screen printing, digital printing, or pad printing.

Coupled or interposed with the IML decoration film 28 may be the FPC assembly 30. The FPC assembly 30 comprises a touch driver 34 and an LED driver 36 with distinct touch and light areas. The touch driver 34 may manage the detection and interpretation of a user's touch inputs. The LED driver 36 may power the LED components providing consistent illumination, adjusting brightness levels, and managing color changes. The FPC assembly 30 may further include a light plus touch film (described but not shown). The light plus touch film may provide a singular integration of the distinct touch-sensitive and light emitting areas. The casing of the user interface 26 is formed by the structural plastic 32. This component may provide rigidity and protection to the assembly. In the complete assembly, all the user interface 26 components may be in-molded together with the structural plastic 32, forming a unified user interface 26.

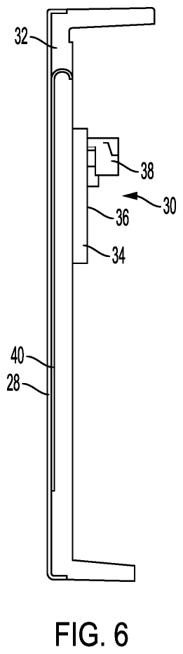

Referring now to FIG. 6, which shows a side profile of the user interface 26 of FIG. 5 with the In-Mold Labeling (IML) decoration film 28, the flexible printed circuit (FPC) assembly 30, the structural plastic 32, the touch driver 34, the LED driver 36, the power connector 38, and a light plus touch film 40. The IML decoration film 28 may function as the visual interface between a user and an appliance by providing printed graphics, icons, or text that guide user interaction. The IML decoration film 28 may lay flush against the FPC assembly 30 and with the structural plastic 32. This may allow touch input registration by the touch driver 34 while also accommodating visual and instructional elements. The LED driver 36 may provide illumination while allowing for adjustments in brightness levels as well as color changes. The structural plastic may be seen forming a housing for the components of the user interface 26 providing rigidity and shielding from other components of an appliance the user interface 26 may be installed in.

The power connector 38 may provide electrical connectivity to the components of the user interface 26. The light plus touch film 40 may provide a singular integration of the distinct touch-sensitive and light emitting areas. This may allow the touch driver 34 and the LED driver 36 to work jointly providing for features like dynamic touch-sensitive illumination. For example, the touch-sensitive areas could be programmed to illuminate in a way to guide the user's interactions, such as highlighting buttons as a user approaches. In another example, the touch interactions of a user could trigger localized lighting effects, such as a “ripple” originating from a point of touch.

The descriptions of the various embodiments have been presented for purposes of illustration, but are not intended to be exhaustive or limited to the embodiments disclosed. Many modifications and variations will be apparent to those of ordinary skill in the art without departing from the scope and spirit of the described embodiments.

Aspects of the present embodiments may be embodied as a system, method or computer program product. Accordingly, aspects of the present disclosure may take the form of an entirely hardware embodiment, an entirely software embodiment (including firmware, resident software, micro-code, etc.) or an embodiment combining software and hardware aspects that may all generally be referred to herein as a “module” or “system.” Furthermore, aspects of the present disclosure may take the form of a computer program product embodied in one or more computer readable medium(s) having computer readable program code embodied thereon.

Any combination of one or more computer readable medium(s) may be utilized. The computer readable medium may be a computer readable signal medium or a computer readable storage medium. A computer readable storage medium may be, for example, but not limited to, an electronic, magnetic, optical, electromagnetic, infrared, or semiconductor system, apparatus, or device, or any suitable combination of the foregoing. More specific examples (a non-exhaustive list) of the computer readable storage medium include the following: an electrical connection having one or more wires, a portable computer diskette, a hard disk, a random access memory (RAM), a read-only memory (ROM), an erasable programmable read-only memory (erasable programmable read-only memory (EPROM) or Flash memory), an optical fiber, a portable compact disc read-only memory (CD-ROM), an optical storage device, a magnetic storage device, or any suitable combination of the foregoing. In the context of this document, a computer readable storage medium may be any tangible medium that can contain, or store a program for use by or in connection with an instruction execution system, apparatus, or device.

Aspects of the present disclosure are described above with reference to flowchart illustrations and/or block diagrams of methods, apparatus (systems) and computer program products according to embodiments of the disclosure. It will be understood that each block of the flowchart illustrations and/or block diagrams, and combinations of blocks in the flowchart illustrations and/or block diagrams, can be implemented by computer program instructions. These computer program instructions may be provided to a processor of a general-purpose computer, special purpose computer, or other programmable data processing apparatus to produce a machine, such that the instructions, which execute via the processor of the computer or other programmable data processing apparatus, enable the implementation of the functions/acts specified in the flowchart and/or block diagram block or blocks. Such processors may be, without limitation, general purpose processors, special-purpose processors, application-specific processors, or field-programmable.

While exemplary embodiments are described above, it is not intended that these embodiments describe all possible forms of the invention. Rather, the words used in the specification are words of description rather than limitation, and it is understood that various changes may be made without departing from the spirit and scope of the invention. Additionally, the features of various implementing embodiments may be combined to form further embodiments of the invention.

1. A display structure for an appliance, comprising:
a fascia panel; and
a flexible printed circuit (FPC) including a touch film having touch-responsive components wherein the FPC is integrated with the fascia to form a unified display structure assembly; and
a resistive substance incorporated between the fascia panel and the FPC for thermal insulation.

2. The display structure of claim 1, wherein the fascia is formed of a polymeric material.

3. The display structure of claim 1, wherein the FPC is adhered to the fascia panel in a single seamless assembly.

4. The display structure of claim 3, wherein the fascia panel is configured to be flexible around a non-linear curvature.

5. The display structure of claim 3, wherein the fascia panel defines a forward-facing surface and a rear-facing surface opposite the forward-facing surface, with the FPC being bonded to the rear-facing surface.

6. The display structure of claim 1, wherein the resistive substance is selected from at least one of potting or plastic.

7. The display structure of claim 1, further comprising a graphics film adjacent to the FPC, wherein the FPC and a graphics film form a unified assembly with distinct regions, one for each of touch interactivity and illumination feedback.

8. The display structure of claim 7, wherein the FPC further comprises an integrated touch driver and a Light Emitting Diode (LED) driver.

9. The display structure of claim 1, further comprising a tail structure, extending perpendicularly from the touch film, wherein during assembly, a device arm secures the tail structure.

10. The display structure of claim 1, further comprising silicone disposed between the fascia panel and the FPC configured to prevent shear.

11. A display structure for an appliance comprising:
a plastic housing;
a graphics film positioned adjacent to the plastic housing;
a flexible printed circuit (FPC) interposed between the graphics film and the plastic housing, the FPC having touch areas and light areas providing touch interactivity and illumination feedback; and
silicone disposed between the fascia and the FPC to prevent shear.

12. The display structure of claim 11, wherein the FPC is joined to a fascia panel in a seamless assembly.

13. The display structure of claim 11, further comprising a touch film integrated with the FPC.

14. The display structure of claim 11, wherein the FPC includes a touch driver and a Light Emitting Diode (LED) driver.

15. The display structure of claim 11, wherein the touch areas of the FPC of at least one of silver traces, Indium Tin Oxide, or polymer dot technology.

16. The display structure of claim 11, wherein the plastic housing of the display structure is formed one of In-Mold Labeling, In-Mold Decorating and pad printing.

17. A display device for an appliance comprising:
a flexible printed circuit (FPC) with touch-sensitive components directly bonded to a touch film;
a fascia combined with the touch film and the FPC encapsulated by a plastic;
silicone disposed between the fascia and the FPC to prevent shear; and
a tail extending from the touch film to be held by a device during assembly.
